(19) United States
(12) Patent Application Publication
(10) Pub. No.: US 2009/0226286 A1
(43) Pub. Date: Sep. 10, 2009

(54) WAFER LIFT-OUT APPARATUS AND SEMICONDUCTOR APPARATUS MANUFACTURING METHOD

(75) Inventor: Kunimitsu MIKAMI, Sakata-shi (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SEIKO EPSON CORPORATION, Shinjuku-ku (JP)

(21) Appl. No.: 12/398,976

(22) Filed: Mar. 5, 2009

(30) Foreign Application Priority Data
Mar. 6, 2008 (JP) 2008-056158

(51) Int. Cl. H01L 21/683

(52) U.S. Cl. 414/225.01; 414/806

(57) ABSTRACT

A wafer lift-out apparatus for lifting out, from a container in which a plurality of semiconductor wafers and a spacer are housed in such a manner that the semiconductor wafers and the spacer are alternately stacked and that a part of the spacer is exposed from between the semiconductor wafers, one of the semiconductor wafers includes: a wafer suction mechanism for sucking the semiconductor wafers; a carrying mechanism for carrying the wafer suction mechanism; and a spacer retaining mechanism for retaining the part of the spacer. The spacer retaining mechanism retains the part of the spacer when the carrying mechanism lifts up the wafer suction mechanism while the wafer suction mechanism sucks one of the semiconductor wafers housed in the container.

The entire disclosure of Japanese Patent Application No: 2008-056158, filed Mar. 6, 2008 is expressly incorporated by reference herein.

### BACKGROUND

1. Technical Field

The present invention relates to a wafer lift-out apparatus and a semiconductor apparatus manufacturing method that are allowed to reliably separate a semiconductor wafer from a spacer when lifting out the semiconductor wafer housed in a container.

2. Related Art

In recent years, the outer diameters of semiconductor wafers used when manufacturing semiconductor apparatuses have been increased. Also, with the slimming-down of the packages of semiconductor apparatuses, the thicknesses of semiconductor wafers used when manufacturing semiconductor chips have been reduced. In order to convey such slimmed-down semiconductor wafers of larger diameter, a Tupperware (registered trademark), a container made of polyethylene, is used.

A Tupperware (registered trademark) is composed of a circumferential wall and a bottom plate that are integrally formed, and a lid. The circumferential wall having an inner diameter that accommodates the outer diameter of a semiconductor wafer leaving a little room is disposed upright on a bottom plate in a cylindrical shape divided at multiple locations. A cushion material is laid on a bottom portion inside the circumferential wall. The predetermined number of semiconductor wafers and spacers (e.g., interlayer paper sheets) are housed in such a manner that the semiconductor wafers and spacers are alternately stacked on the cushion material. The lid is set to cover the circumferential wall. Therefore, even slimmed-down semiconductor wafers of larger diameter are conveyed without causing a problem, by stacking the semiconductor wafers with the spacers therebetween in the container.

FIGS. 6 and 7 are drawings schematically showing a method for lifting out a semiconductor wafer 16 from a Tupperware (registered trademark) serving as a container 102a using a wafer lift-out apparatus.

First, as shown in FIG. 6, a wafer suction mechanism 104 mounted on a carrying arm 103 is carried to above the container 102a and then the wafer suction mechanism 104 is lowered into the container 102a by the carrying arm 103. Semiconductor wafer 16 and 17 and an interlayer paper sheet 18 are housed in the container 102a in an alternately stacked manner.

Next, as shown FIG. 7, the wafer suction mechanism 104 vacuum-sucks the semiconductor wafer 16 and then the carrying arm 103 lifts up the wafer suction mechanism 104 sucking the semiconductor wafer 16. At that time, ionizers 115a and 115b send an ion blow 22 into the container from both sides of the container 102a. Thus, the interlayer paper sheet 18 and semiconductor wafer 16 are separated so that the interlayer paper sheet 18 is prevented from adhering to the semiconductor wafer 16 sucked by the wafer suction mechanism 104 (see JP-A-2002-246433 (paragraphs 0040 to 0045, FIGS. 2 to 4)).

Subsequently, the semiconductor wafer 16 lifted out from the container 102a is attached to a dicing tape.

However, as for the above-mentioned related-art wafer lift-out apparatus, even if an ion blow is sent onto the side surfaces of the semiconductor wafer 16 and interlayer paper sheet 18 serving as a spacer, the blow may not pass through between the semiconductor wafer 16 and spacer if the semiconductor wafer 16 and spacer adhere to each other by static electricity. In this case, the semiconductor wafer 16 may not be separated from the spacer. That is, the interlayer paper sheet disadvantageously remains adhering to the semiconductor wafer sucked by the wafer suction mechanism 104.

### SUMMARY

An advantage of the invention is to provide a wafer lift-out apparatus and a semiconductor apparatus manufacturing method that are allowed to reliably separate a semiconductor wafer from a spacer when lifting out the semiconductor wafer housed in a container.

According to a first aspect of the invention, a wafer lift-out apparatus for lifting out, from a container in which a plurality of semiconductor wafers and a spacer are housed in such a manner that the semiconductor wafers and the spacer are alternately stacked and that a part of the spacer is exposed from between the semiconductor wafers, one of the semiconductor wafers includes: a wafer suction mechanism for sucking the semiconductor wafers; a carrying mechanism for carrying the wafer suction mechanism; and a spacer retaining mechanism for retaining the part of the spacer. The spacer retaining mechanism retains the part of the spacer when the carrier lifts up the wafer suction mechanism while the wafer suction mechanism sucks one of the semiconductor wafers housed in the container.

By adopting the wafer lift-out apparatus according to the first aspect of the invention, one of the semiconductor wafers is reliably separated from the spacer by mechanically retaining the spacer that should be separated.

In the wafer lift-out apparatus according to the first aspect of the invention, the spacer retaining mechanism preferably includes: an elastic body mounted on the carrying mechanism; and a retaining unit mounted at a tip of the elastic body.

In the wafer lift-out apparatus according to the first aspect of the invention, the elastic body is preferably one of a spring and rubber.

In the wafer lift-out apparatus according to the first aspect of the invention, the spacer retaining mechanism preferably includes: an air cylinder; and a retaining unit mounted on the air cylinder.

In the wafer lift-out apparatus according to the first aspect of the invention, the spacer retaining mechanism preferably jets compressed air.

According to a second aspect of the invention, a semiconductor apparatus manufacturing method includes lifting out, from a container in which a plurality of semiconductor wafers and a spacer are housed in such a manner that the semiconductor wafers and the spacer are alternately stacked and that a part of the spacer is exposed from between the semiconductor wafers, one of the semiconductor wafers. When a wafer suction mechanism is lifted up while the wafer suction mechanism sucks one of the semiconductor wafers housed in the container, the one of the semiconductor wafers is separated from the spacer by retaining the part of the spacer.

### BRIEF DESCRIPTION OF THE DRAWINGS

The invention will be described with reference to the accompanying drawings, wherein like reference numerals designate like elements.

FIG. 1 is a plan view schematically showing an overall structure of a mount apparatus including a wafer lift-out apparatus according to an embodiment of the invention.

FIG. 2 is a drawing schematically showing a method for lifting out a wafer using the wafer lift-out apparatus shown in FIG. 1.

FIG. 3 is a drawing schematically showing a method for lifting out a wafer using the wafer lift-out apparatus shown in FIG. 1.

FIG. 4 is a drawing schematically showing a method for lifting out a wafer using the wafer lift-out apparatus shown in FIG. 1.

FIG. 5 is a drawing schematically showing a method for lifting out a wafer using the wafer lift-out apparatus shown in FIG. 1.

FIG. 6 is a drawing schematically showing a method for lifting out a wafer from a Tupperware (registered trademark) serving as a container using a wafer lift-out apparatus.

FIG. 7 is a drawing schematically showing the method for lifting out a wafer from a Tupperware (registered trademark) serving as a container using a wafer lift-out apparatus.

### DESCRIPTION OF EXEMPLARY EMBODIMENTS

Now, embodiments of the invention will be described with reference to the accompanying drawings.

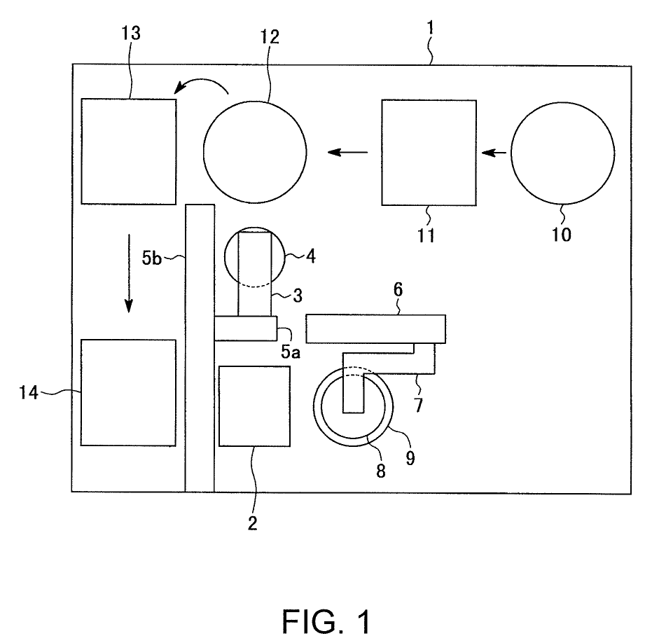

FIG. 1 is a plan view schematically showing an overall structure of a mount apparatus including a wafer lift-out apparatus according to an embodiment of the invention.

The mount apparatus shown in FIG. 1 automatically performs a mount process of automatically lifting out a slimmed-down semiconductor wafer of larger diameter from a container made of polyethylene and aligning the semiconductor wafer, then attaching the semiconductor wafer to an adhesive tape attached to a ring frame, placing the ring frame onto a reverse placement unit, and then housing the ring frame in a cassette of a cassette case. A wafer mount line is linearly set in an upper part of FIG. 1 on a base 1. Disposed below the wafer mount line are a carrying arm 3 of the wafer lift-out apparatus for lifting out a wafer from a container 2 and an alignment apparatus.

The above-mentioned wafer mount line is formed by linearly disposing a ring frame supply unit 10, a tape attachment unit 11, a wafer mount unit 12, and the reverse placement unit 13. A semiconductor wafer placed on the reverse placement unit 13 is housed in a cassette (not shown) of a cassette case 14. The ring frame supply unit 10 supports multiple ring frames (not shown) on a lifting table thereof. Each time a ring frame is taken out, the lifting table intermittently ascends by the thickness of the ring frame. The tape attachment unit 11 attaches an adhesive tape (not shown) to the upper surface of a ring frame taken out from the ring frame supply unit 10 with the adhesive surface of the adhesive tape directed downward and cuts the attached adhesive tape along the perimeter of the ring frame. The wafer mount unit 12 overlays is a tape-attached ring frame provided by the tape attachment unit 11 on a semiconductor wafer sucked and held on a suction table, and attaches the semiconductor wafer to the adhesive tape of the ring frame in a vacuum chamber by applying pressure. The reverse placement unit 13 receives the semiconductor wafer-attached ring frame from the wafer mount unit 12 in such a manner that the ring frame is reversed.

In the wafer mount unit 12, a semiconductor wafer is provided onto the suction table in such a manner that a circuit pattern of the semiconductor wafer is directed downward and the back surface thereof is directed upward, and an adhesive tape is attached to the back surface. In the reverse placement unit 13, a circuit pattern of a semiconductor wafer is directed upward.

In some cases, a protection tape is attached to the entire circuit pattern surface of a semiconductor wafer and the protection tape is stripped off before a dicing process.

The container 2 in which semiconductor wafers and an interlayer paper sheet serving as a spacer are housed in an alternately stacked manner includes a placement unit. A wafer alignment unit and the wafer mount unit 12 are aligned in an X axis direction perpendicular to the wafer mount line. The carrying arm 3 of the semiconductor wafer suction/lift-out apparatus is configured so that the carrying arm is freely moved in the vertical direction as well as X axis direction by a vertical movement mechanism 5a and an X axis direction movement mechanism 5b. The wafer lift-out apparatus is a mechanism that successively lifts out a semiconductor wafer from the container 2 and carries the lifted-out semiconductor wafer from the wafer alignment unit to the wafer mount unit 12. A spacer suction/carrier 8 is configured so that it is freely moved in a vertical direction as well as a Y axis direction parallel with the wafer mount line by a carrying arm 7. A spacer lift-out mechanism 6 includes a carrier 8 and a spacer housing box 9 for housing a spacer lifted out from the container 2.

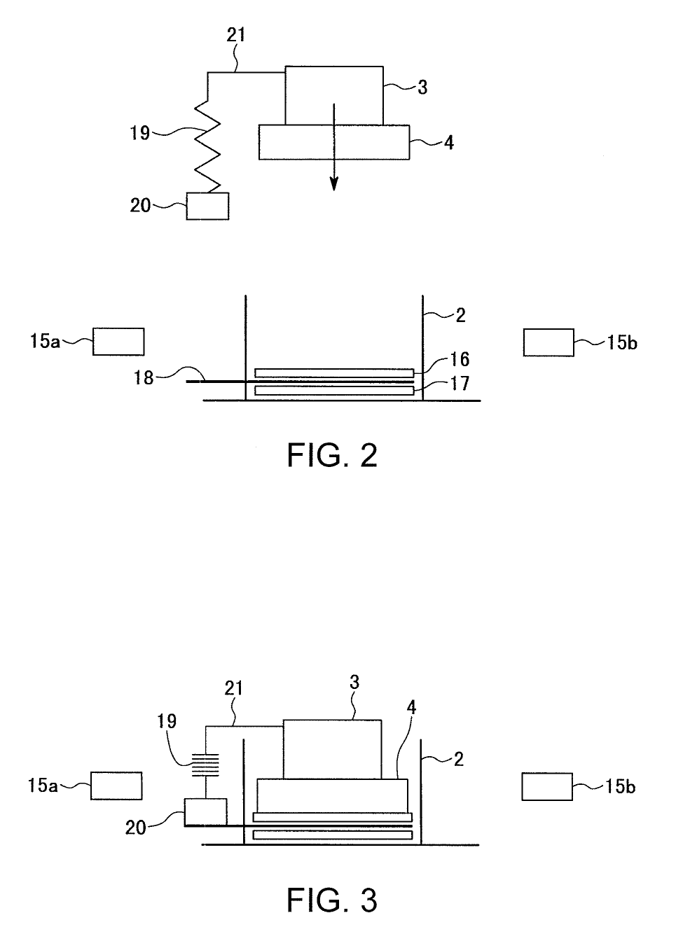

Next, the wafer lift-out apparatus will be described in detail with reference to FIGS. 2 to 5. FIGS. 2 to 5 are drawings schematically showing a method for lifting out a wafer using the wafer lift-out apparatus shown in FIG. 1.

As shown in FIGS. 2 to 5, the wafer lift-out apparatus includes the carrying arm 3, a wafer suction mechanism 4 mounted on the carrying arm 3, a spacer retaining mechanism 21 mounted on the carrying arm 3, and ionizers 15a and 15b disposed on both sides of the container 2.

The carrying arm 3 is vertically freely moved by the vertical movement mechanism 5a shown in FIG. 1. The wafer suction mechanism 4 sucks the semiconductor wafers 16 and 17 by vacuum suction. The spacer retaining mechanism 21 has a retaining unit 20 at its tip. The retaining unit 20 is coupled to the carrying arm 3 with a spring 19 therebetween. The ionizers 15a and 15b send an ion blow 22 from both sides of the container 2 into the container 2.

Next, the method for lifting out a semiconductor wafer using the wafer lift-out apparatus will be described.

First, as shown in FIG. 2, the carrying arm 3 carries the wafer suction mechanism 4 to above the container 2 and then lowers it into the container 2. Here, it is assumed that the semiconductor wafers 16 and 17 and interlayer paper sheet 18 are housed in the container 2 in an alternately stacked manner and that the interlayer paper sheet 18 is formed in a larger size than that of the semiconductor wafers 16 and 17 and therefore a part of the interlayer paper sheet 18 is exposed from between the stacked semiconductor wafers 16 and 17.

When the carrying arm 3 is lowered as described above, the retaining unit 20 of the spacer retaining mechanism 21 makes contact with the exposed part of the interlayer paper sheet 18 and, at the same time, the spring 19 shrinks. Subsequently, the wafer suction mechanism 4 makes contact with the semiconductor wafer 16 and vacuum-sucks it. This state is shown in FIG. 3.

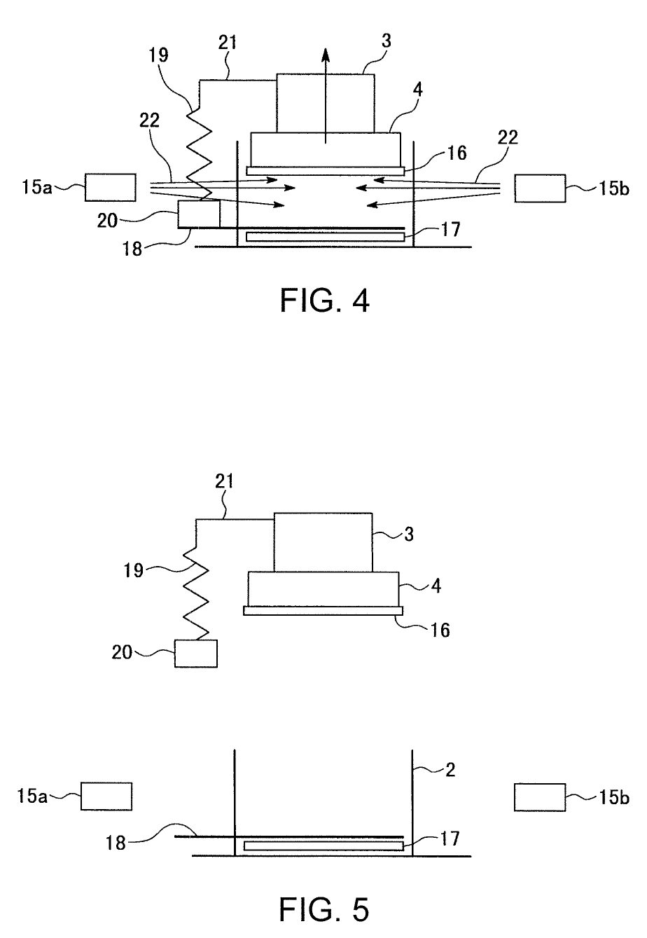

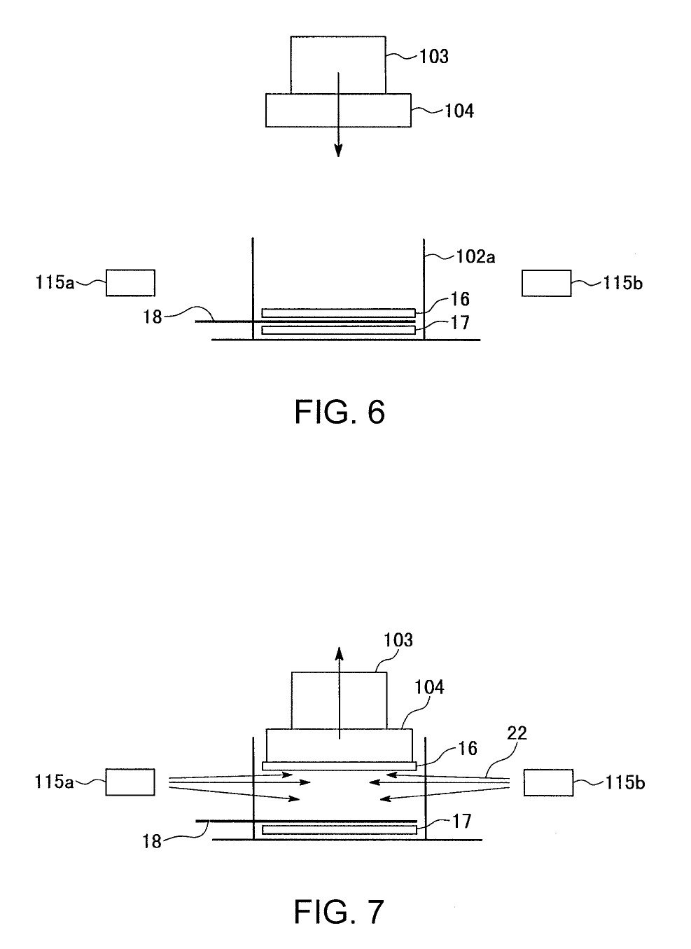

Next, as shown in FIG. 4, the carrying arm 3 is lifted up together with the semiconductor wafer 16 sucked by the wafer suction mechanism 4. At that time, the ionizers 15a and 15b send the ion blow 22 from both sides of the container 2. In this case, a gap is forcefully made between the semiconductor wafer 16 and interlayer paper sheet 18 since the part of the interlayer paper sheet 18 retained by the retaining unit 20 is kept retained by the force of the spring 19 even if the wafer suction mechanism 4 is lifted up. Since the ion blow 22 is sent into the gap, the ion blow 22 reliably passes through the gap. As a result, the semiconductor wafer 16 is reliably separated from the interlayer paper sheet 18.

Subsequently, as shown in FIG. 5, the carrying arm 3 is further lifted up so that the semiconductor wafer 16 is lifted out from the container 2. Subsequently, a process of attaching the lifted-out semiconductor wafer 16 to a dicing tape is performed.

The related art is unreliable in separating a semiconductor wafer from an interlayer paper sheet because a semiconductor wafer may not be separated from an interlayer paper by an ion blow depending on the adhesiveness between the semiconductor wafer and interlayer paper. On the other hand, in this embodiment, the interlayer paper sheet 18 that should be separated is retained mechanically so that an ion blow reliably passes through. Thus, the semiconductor wafer 16 and interlayer paper sheet 18 are reliably separated.

A semiconductor apparatus manufacturing method according to another embodiment of the invention includes the process shown in FIGS. 2 to 5. That is, this semiconductor apparatus manufacturing method includes the process of lifting out the semiconductor wafer 16 from the container 2 in which the semiconductor wafers 16 and 17 and interlayer paper sheet 18 serving as a spacer are housed in an alternately stacked manner and from which a part of the interlayer paper sheet 18 is exposed. In the process, the semiconductor wafer 16 is separated from the interlayer paper sheet 18 by retaining the part of the interlayer paper sheet 18 when the wafer suction mechanism 4 is lifted up while the wafer suction mechanism 4 sucks the semiconductor wafer 16 housed in the container 2.

The invention is not limited to the above-mentioned embodiments and various changes can be made to the embodiments. For example, in the above-mentioned embodiments, the spacer retaining mechanism 21 has the retaining unit 20 at its tip and the retaining unit 20 is coupled to the carrying arm 3 with the spring 19 therebetween, but not limited thereto. Another type of spacer retaining mechanism may be used as long as the spacer retaining mechanism retains the part of the interlayer paper sheet 18 when the wafer suction mechanism 4 is lifted up by a carrying mechanism while the wafer suction mechanism 4 sucks the semiconductor wafer 16 housed in the container 2. For example, the following spacer retaining mechanisms may be used.

For example, a spacer retaining mechanism using another elastic body (e.g., rubber) instead of the spring 19 may be used. Also, the wafer suction mechanism 4 and spacer retaining mechanism 21 do not always need to be coupled to each other via the carrying arm 3 therebetween. For example, a spacer retaining mechanism that includes an air cylinder, which is independent of the wafer suction mechanism 4, and the retaining unit 20 mounted to the air cylinder and retains a part of the spacer 18 by moving the retaining unit 20 using the air cylinder may be used. Also, a spacer retaining mechanism that retains the part of the spacer 18 using a mechanism that jets compressed air may be used.

While the interlayer paper sheet 18 is used as a spacer in the above-mentioned embodiments, a material (e.g., a resin, plastic, chemical fibers, or a mixture thereof) other than paper may be used as long as the material is a thin sheet.

While an example where the retaining unit 20 of the spacer retaining mechanism retains one location of the spacer is used in the above-mentioned embodiments, a spacer retaining mechanism that is provided with multiple retaining units 20 so as to retain multiple locations of the spacer may be used.

What is claimed is:

1. A wafer lift-out apparatus for lifting out, from a container in which a plurality of semiconductor wafers and a spacer are housed in such a manner that the semiconductor wafers and the spacer are alternately stacked and that a part of the spacer is exposed from between the semiconductor wafers, one of the semiconductor wafers, the wafer lift-out apparatus comprising:
a wafer suction mechanism for sucking the semiconductor wafers;
a carrying mechanism for carrying the wafer suction mechanism; and
a spacer retaining mechanism for retaining the part of the spacer, wherein
the spacer retaining mechanism retains the part of the spacer when the carrying mechanism lifts up the wafer suction mechanism while the wafer suction mechanism sucks one of the semiconductor wafers housed in the container.

2. The wafer lift-out apparatus according to claim 1, wherein
the spacer retaining mechanism includes:
an elastic body mounted on the carrying mechanism; and
a retaining unit mounted at a tip of the elastic body.

3. The wafer lift-out apparatus according to claim 2, wherein
the elastic body is one of a spring and rubber.

4. The wafer lift-out apparatus according to claim 1, wherein
the spacer retaining mechanism includes:
an air cylinder; and
a retaining unit mounted on the air cylinder.

5. The wafer lift-out apparatus according to claim 1, wherein
the spacer retaining mechanism jets compressed air.

6. A semiconductor apparatus manufacturing method, comprising
lifting out, from a container in which a plurality of semiconductor wafers and a spacer are housed in such a manner that the semiconductor wafers and the spacer are alternately stacked and that a part of the spacer is exposed from between the semiconductor wafers, one of the semiconductor wafers, wherein
when a wafer suction mechanism is lifted up while the wafer suction mechanism sucks one of the semiconductor wafers housed in the container, the one of the semiconductor wafers is separated from the spacer by retaining the part of the spacer.
